(19) United States
(12) Patent Application Publication
(10) Pub. No.: US 2006/0225997 A1
(43) Pub. Date: Oct. 12, 2006

(54) MAGNETRON WITH IN-SITU CLEANING TARGET AND ITS APPLICATION METHOD

(75) Inventor: Yang LIU, Beijing (CN)

Correspondence Address: AKIN GUMP STRAUSS HAUER & FELD L.L.P., ONE COMMERCE SQUARE, 2005 MARKET STREET, SUITE 2200, PHILADELPHIA, PA, 19103, US

(73) Assignees: Beijing Powertech Co., Ltd., Beijing (CN); Yang Liu, Beijing (CN)

(21) Appl. No.: 11/279,155

(22) Filed: Apr. 10, 2006

(30) Foreign Application Priority Data
Apr. 8, 2005 (CN) 200510063432.8

(51) Int. Cl. C23C 14/32; C23C 14/00

(52) U.S. Cl. 204/192.1; 204/298.16

(57) ABSTRACT

This invention provides a magnetron and its application method. The magnetron has a function of in-situ cleaning and can be used to prevent the pollution problem during the ion etching and cleaning. The target of the magnetron can be rotated around its central axis by controlling the inner magnetic field to form two sputtering race-tracks. The cleaning anode and the gas circuit device are set in the local space; after feeding the inert gas, the main sputtering power supply, connected between the target and the main anode of the coater, is used for the sputtering deposition, and the assistant cleaning power supply, connected between the target and the cleaning anode in the local space, is used for sputtered etching and cleaning the target surfaces. The purpose of continuously in-situ cleaning the whole target surface can be reached in that the magnetron target is continuously rotated and the related azimuth of the two sputtering race-tracks is kept constant. As a result, a stabile working state of magnetron sputtering on the target surface is ensured, the deposition rate of the compound films on the substrates is developed, and the process reproducibility can be basically certain. Moreover, using this invention is convenient to carry on the ion etching and cleaning for the target, so as to prevent the pollution of the surfaces of substrates and the cross contamination between the targets.

### BACKGROUND OF THE INVENTION

This invention belongs to the technical field of PVD (Physical Vapor Deposition), concretely belongs to sputtering technology, and more concretely belongs to magnetron sputtering equipment and its application method.

During the reactive sputtering deposition process, a compound film will be gradually formed on the target surfaces under effect of the reactive gases, thus the normal working state of the targets is changed, even inducing the poisoning of the target surfaces. In addition, some other problems may also be encountered during presputtered cleaning of the target surfaces, e.g., the surface pollution on the substrates to be deposited may be easily brought, and the cross contamination among the targets may easily induced during presputtered cleaning of the multi-magnetrons; these problems has seriously affected the research, the development and the industrial applications of sputtering deposition. Thus, there exists a need to find out a simple and effective solution for this matter.

U.S. Pat. No. 4,981,550 discloses a method for preparing a metallized semiconductor circuit, wherein a plasma etching method is used to etch a window on the contact material. During conducting the etching, the inert gas (such as argon gas) source is used to carry on the sputtering cleaning for the buffer layer. U.S. Pat. No. 5,419,822 discloses a method for depositing a ultra-thin film on a substrate. Deposit a silicon dioxide film on a silicon substrate at first. Then place the substrate on a substrate holder within a coating chamber. And use argon gas as an ionized gas to carry on etching the substrate, meanwhile deposit Ti onto the substrate. In this way, the extra layer is deposited simultaneously during conducting cleaning on the surface. The methods provided in the above two patents actually are the methods of carrying on the sputtering cleaning of substrate to be deposited, but the target cleaning issue is not mentioned therein.

U.S. Pat. No. 5,772,858 discloses a process and apparatus for cleaning a planar target in a magnetron sputtering source to remove the sputtering particles on the target surface and make a uniform etching on the target surface. There are magnetron assembly, a shutter mechanism, D.C. and R.F. power supply in the coating chamber, and means for alternatively switching the power sources for sputter deposition and target cleaning. During the operational process, apply D.C. power supply to the target between the magnetic poles of the magnetron assembly at first to carry on coating on the substrate. Then, remove the treated substrates out of the coating chamber, separate the target and the substrate holder using the cover mask in the interval of the removing procedure. And then apply R.F. power supply to the chamber to form a plasma, and thus to remove the sputtering particles previously deposited on the target. The idea of separating the sputtering coating process and the target cleaning process and carrying out the two processes in turns is mentioned in this patent. Also provided is the supply method of the power sources.

U.S. Patent 2004/0163943A1 and U.S. Patent 2005/0051422A1 both disclosed a rotatable cylindrical magnetron, using a new technique adopted gradually and widely in recent several years, i.e., utilizing a single sputtering “race-track” to conduct the sputtering scanning along the target surface through the rotating target, so as to carry on the sputtering coating at high voltage and current levels. Further, through increasing the magnetic field density of the target ends makes the sputtering enhanced and the sputtering extended to the two ends of the target, so as to overcome the shortcoming of the unsputtered ‘dead zones’ left at the two ends of the target in the ordinary magnetron sputtering. As a result, accumulation of condensate in surfaces at the two ends of the magnetron target tube can be effectively reduced, along with the resultant arcing due to the condensate accumulated during a long term; the inventors call this as “self cleaning”, and further provide the more uniform coating. It is stated in the patent that improving the electrical isolation and the cooling systems makes the high power sputtering available at the target ends. However, a shortcoming of using the patent technique stands in that, the entire target surface always exposes in the reactive gas atmosphere, and only the small single sputtering race-track involved zone is in sputtering state while most part of the target tube surface are in unsputtering area.

TW Patent No. 510924 discloses a magnetron and a cleaning method of its target surface. The method includes the following procedures: using a first reactive gas to perform the first ion bombardment to the target in a first reaction stage, and using a second reactive gas to perform the ion bombardment in the second stage for the target cleaning, in which the kinetic energy, atomic radius and atomic weight of the first reactive gas are uniformly larger than those of the second reactive gas. Actually, the patent provides a target cleaning method in the different stages, but not cleaning at the same time of sputtering.

In prior magnetron designs, there was no more than one sputtering racetrack, only the single sputtering racetrack and the small zone near it are in sputtering state, while most part of the target tube surface is in unsputtering zone at each moment during a cycle of the sputtering racetrack scanning along the target surface, so the rapid poisoning and pollution on the target surface are difficult to be prevented. Virtually, the purposes of both the sputtering deposition and the sputtered cleaning are hard to be realized simultaneously.

### BRIEF SUMMARY OF THE INVENTION

In order to solve the pendent problems mentioned above, the present invention provides a magnetron and its application method, in which the magnetron has a function of in-situ cleaning and can be used to prevent the pollution occurred during the process of pre-sputtering cleaning.

To realize the above purposes, this invention provides a magnetron target of which includes: a rotatable magnetron target which may rotate around its central axis, a closed local space formed with shield wall around most part of the area along the target passing route, in which the inert gas is fed. During the working process of the reactive sputtering deposition, each sputtering part on the target and its vicinal area can periodically enter into the said local space by the target rotating and then is etched and cleaned by ions of the inert gas, so as to stably control the formation condition of the compound films on the magnetron target and to avoid the target surface from poisioning.

To be specific, the shape of the magnetron target is cylindrical tube (or disk or circular ring), and the target can rotate around its central axis. Being in the shape of cylindrical tube, two sputtering race-tracks parallel to the axis and with a substantially predetermined emitting azimuth are formed on the outer surface of the target by controlling the inner magnetic field of the target: the first sputtering race-track faces to the substrates to be deposited in the sector solid angle space within the chamber of the coater, and the first race-track is energized and glowed by the equipped main sputtering power supply to carry on the reactive sputtering deposition; the second sputtering race-track lies in the back or the side face of the first sputtering race-track. When the target is disk or circular ring, two sputtering race-tracks with the pre-determined emitting azimuth formed on the outer working surface of the disk or circular ring target by controlling the inner magnetic field of the target. The first sputtering race-track lies in the sector zone facing to the azimuth of the substrates to be deposited in the coater chamber; the second sputtering race-track lies in another part of the sector zone, and the first sputtering race-track is energized and glowed by the equipped main sputtering power supply to carry on the reactive sputtering coating, and the second race-track is energized and glowed by the equipped assistant power supply for the etching and cleaning to carry on the ion sputtering etching and cleaning, the wastes are kept in the closed local space formed by the shield wall; a local space is formed using the shield wall in the part around area of the target passing route, where inert gas is fed in and the cleaning anode and the gas distribution device are set in, feeding the inert gas makes the gas pressure of the local space little higher than (or equal to) that of the reactive coating space. The main sputtering power supply (DC (direct current) or pulsed or RF (radio frequency) power supply, etc.) is connected between the target and the main anode of the coater (normally means the metal wall of the coater chamber), or an AC (alternating current) sputtering power supply is connected between the two targets, energizing the glowing sputtering at the first sputtering race-track to conduct the sputtering coating. The assistant power supply for the etching and cleaning is connected between the target and the cleaning anode in the local space, energizing the glowing sputtering at the second sputtering race-track to sputter and etch-clean the target surface. The above mentioned main sputtering power supply and assistant etching and cleaning power supply can be separately set or combined into one power supply.

The application method of such in-situ cleaning magnetron is: during the process of the reactive sputtering deposition, the sputtering zone and its vicinal zone on the magnetron target surface are periodically turned into the local space and then are etched and cleaned by the ions of the inert gas, as a result, the formation condition of the compound film on the target surface can be stably controlled, and the state of target poisoning can be avoided. When the target conducts the reactive sputtering at the glowing position of the first sputtering race-track, the target is also cleaned in a certain degree by the ions of the inert gas at the glowing position of the second sputtering race-track. In this way, while the target surface is rotating continuously, the relative azimuthes of the two sputtering race-tracks are kept constant, so the whole target surface is cleaned in-situ thoroughly; the compound film on the target surface, formed in the reactive coating space, are partly or totally sputtered and cleaned away by the inert gas ions from the glowing position of the second sputtering race-track when the target is turned into the inert gas atmosphere in the local space through the target rotating, making the state of the target surface turning or turned from the compound state into the metal state thoroughly when the part of the target surface is returned into the reactive sputtering coating area at the second time. The continuous in-situ target cleaning is carried on in such a circle. Even in condition that the reactive gas concentration is relatively high in the reactive coating space, the normal sputtering working state on the whole target surface can be kept stably in a certain degree for a long time, and the ratio of the formation and removal of the compound films on the target surface can reach a dynamic balance for a long time in a certain degree that the process needs, so as to avoid the target material turning into the poisoned state. Thus, develop the deposition rate of the compound films on the substrates, and keep the continuous stability of the process.

The favorable effect of this invention is obvious. It was verified according to our experiments that: the magnetrons manufactured according to this invention and the related techniques, such as the cylindrical tube shaped magnetron with a rotatable target and with two long-thin sputtering race-tracks, had the function of continuously in-situ cleaning. That is, on the cylindrical shaped target surface, the main sputtering coating was conducting on a part of the target, meanwhile the ion etching and cleaning was carried on at another part of the target. The sputtering working state on the target surface could be kept stabile even in condition that the reactive gas concentration was relatively high. As a result, the deposition rate of the compound films on the substrates was developed, and the process repeatability could be basically maintained. In this invention, as an alternation, only the cleaning and etching power supply is turned on during the presputtering cleaning procedure, and the target is etched and cleaned using the inert gas ions in the local space, so the surface pollution of the substrates and the cross contamination between or among the magnetrons are prevented.

### BRIEF DESCRIPTION OF THE SEVERAL VIEWS OF THE DRAWINGS

The foregoing summary, as well as the following detailed description of the invention, will be better understood when read in conjunction with the appended drawings. For the purpose of illustrating the invention, there are shown in the drawings embodiments which are presently preferred. It should be understood, however, that the invention is not limited to the precise arrangements and instrumentalities shown.

In the drawings:

FIGS. 1.1 to 1.4 show three schematic diagrams of the long-thin race-tracks and one schematic diagram of the magnetic field in the magnetron, respectively.

FIGS. 2.1 and 2.2 show schematic diagrams of the sputtering race-track 2, used for the etching and cleaning in the local space enclosed by the shield wall.

FIGS. 3.1 and 3.2 show the schematic diagrams of the local space enclosed.

FIG. 4 shows a schematic diagram of two race-tracks, whose axial length of the second race-track to clean target is longer than or equal to that of the first one to deposit thin film.

FIG. 5.1 shows a schematic diagram of a configuration, of which the main sputtering power supply and the assistant power supply for the etching and cleaning are separately set.

FIG. 5.2 shows a schematic diagram of a configuration, of which the main sputtering power supply (bipolar pulsed AC power supply) and the assistant power supply for the etching and cleaning are separately set.

FIG. 6 shows a schematic diagram of a configuration, of which the main sputtering power supply and the assistant power supply for the etching and cleaning are incorporated into one power supply.

FIG. 7 shows a schematic diagram of one cycle of in-situ cleaning process of target surface.

FIGS. 8.1 and 8.2 show the schematic diagrams that the two sputtering race-tracks jointly use the main anode and are energized by a main sputtering power supply. In FIG. 8.1, the cleaning anode 5 and the main anode (the metal wall of the coater chamber) are connected together; in FIG. 8.2, the two power supplies in one share the part of the main anode in the local space.

FIG. 9 shows a schematic diagram that the target is etched by the sputtering and cleaning with the cleaning anode energized by the assistant power supply for the etching and cleaning in the local space where the inert gas is fed in.

FIGS. 10.1 and 10.2 show the schematic diagrams of in-situ etching and cleaning disc target and circular ring target.

FIG. 11 shows a schematic diagram of closed control loop formed by combining the feedback quantity from the in-situ monitoring spectrum and one of the following three factors: the power of the main sputtering power supply, the power of the assistant power supply for the etching and cleaning and the input flow of the reactive gas.

FIG. 12 shows a schematic diagram of a configuration, where only the assistant power supply for the etching and cleaning is used and the inert gas is fed into the local space, in which the pre etching and cleaning is conducted on the target surface, to prevent the substrates from the surface pollution and the cross contamination among the magnetron targets.

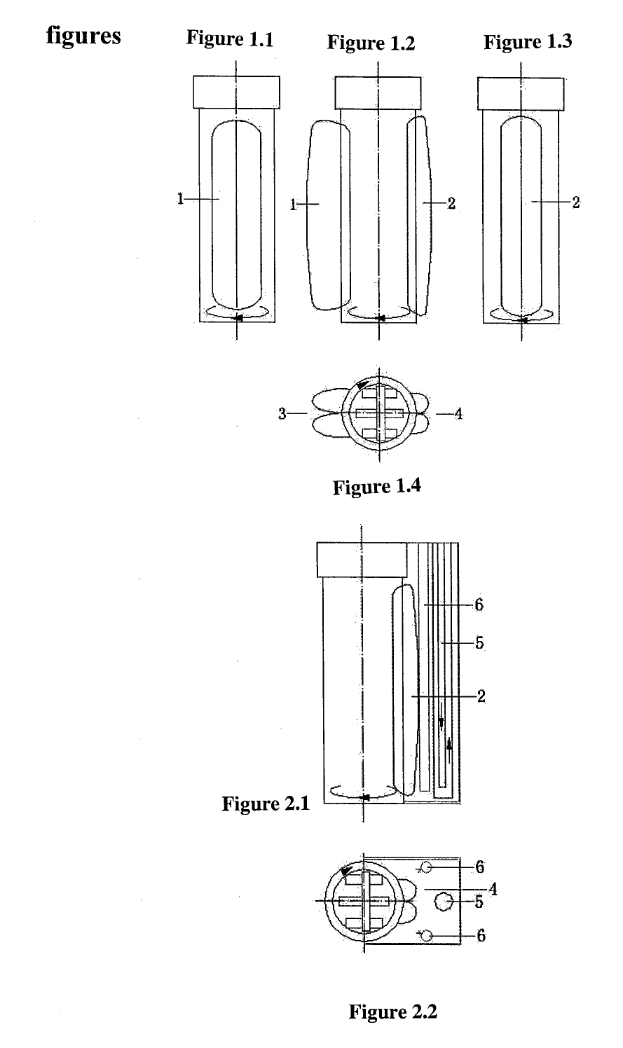

In FIGS. 1 to 12, 1—First sputtering race-track, 2—Second sputtering race-track, 3—Reactive sputtering coating zone in the chamber, 4—Enclosed cleaning and etching space in the chamber, 5—Cleaning anode, 6—Gas pipe, 7—Assistant power supply for the etching and cleaning, 8—Main sputtering power supply, 9—The combined power supply with main sputtering power supply and assistant power supply for etching and cleaning, 10—Compound film, 11—Shield wall, 12—Disc target, 13—Circular ring target, 14—Substrate holder, 15—Target, 16—AC sputtering power supply, 17—Designated area in target surface, 18—Sputtering cleaning glowing, 19—Spectrum detection, 20—Gas control, 21—Main sputtering power supply, 22—Assistant cleaning power supply.

### DETAILED DESCRIPTION OF THE INVENTION

Combining with the attached figures, the invention is further illustrated as follows:

1) The main structure of this invention: the shape of the magnetron target is cylindrical tube (or disc or circular ring), and the target can be rotated around its central axis; two long-thin sputtering race-tracks parallel to the axis and with the basically predetermined emitting orientation on the outer surface of the cylindrical target are formed by controlling the inner magnetic field of the target (shown in FIGS. 1.1 to 1.4): the first sputtering race-track 1 faces to the sector solid angle space within the chamber, and the first race-track is energized and glowed by the equipped main sputtering power supply 8 to carry on the reactive sputtering deposition in the reactive sputtering coating space 3 in the chamber; the second sputtering race-track 2 lies in the back or the side face of target 15, and the second race-track is energized and glowed by the equipped assistant power supply 7 for the cleaning and etching in the enclosed cleaning and etching zone 4 in the chamber to carry on the ion sputtered etching and cleaning. And the wastes are closed in the local space formed by the shield wall (shown in FIG. 2.1 and FIG. 2.2).

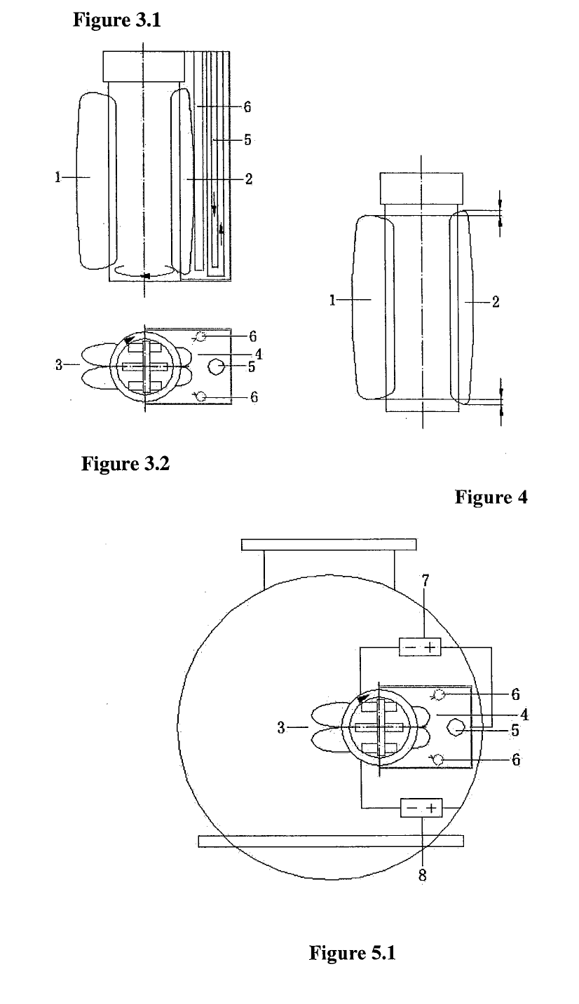

2) Local space structure in this invention: the cleaning anode 5 (normally cooled with cooling water) and gas distribution device are set in the local space, and the gas pipe 6 is set in the gas distribution device; the inert gas (such as argon gas, etc.) is fed through the gas distribution device and makes the pressure P1 in the local space little higher than (or equal to) the pressure P2 in the reactive coating space (shown in FIG. 3.1 and FIG. 3.2).

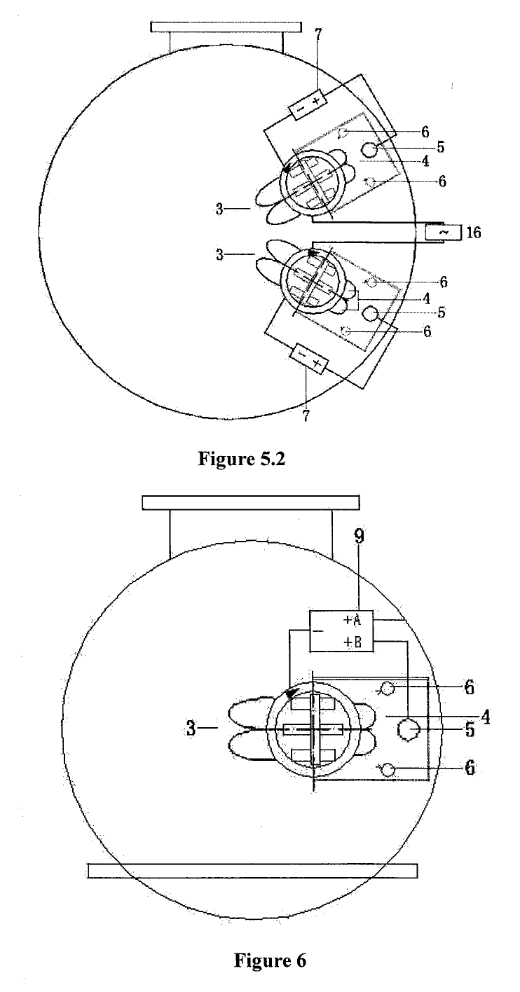

3) Connection method of power supplies in this invention: the main sputtering power supply 8 (DC or pulsed or RF power supply, etc.) is connected between the main anode (normally the metal wall of the coater chamber) and the target, or an AC sputtering power supply (bipolar pulsed power supply) 16 is connected between the two targets, energizing the glowing sputtering at the first sputtering race-track 1 to conduct the reactive sputtering coating; the assistant power supply 7 for the etching and cleaning is connected between the target and the cleaning anode 5 (normally cooled with cooling water), energizing the second sputtering race-track 2 to conduct the glowing sputtering for the sputtered etching and cleaning on the target surface; the main above sputtering power supply 8 and the assistant power supply 7 for the etching and cleaning can be independently set (shown in FIG. 5.1 or FIG. 5.2) or combined into one power supply 9 (shown in FIG. 6).

4) As shown in FIG. 4, the axial lengths of the second race-track is little longer than or equal to that of the first race-track, so as to ensure the working area is fully cleaned.

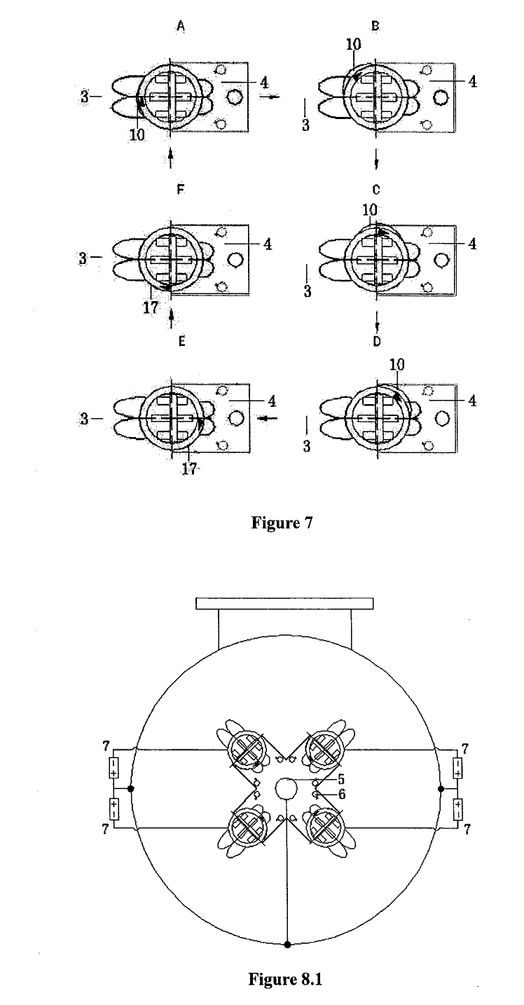

5) A target surface in-situ cleaning process in this invention: when the reactive sputtering is carried on at the glowing position of the first sputtering race-track 1, the target is cleaned in a certain degree by the ions of the inert gas at the glowing position of the second sputtering race-track 2. In this way, the purpose of whole target surface continuously in-situ cleaned can be reached in which the target is continuously rotated and the relative orientation of the two sputtering race-tracks is kept constant. The compound film 10 on the target surface, formed in the reactive coating space, can be partly or totally sputtering cleaned by the inert gas ions from the glowing position of the second sputtering race-track 2 when the target is turned into the inert gas atmosphere in the local space. Through the target rotating, the state of the target surface partly tend into the metal state or fully turn into the metal state when the target surface is turned into the reactive coating zone at the second time. During process that the continuously rotated cylindrical tube (or the disc or the ring) target rotates one cycle, each different position on the target surface passes through the main reactive sputtering area and the cleaning and etching area in turn, respectively: the compound film 10 (A) gradually formed in the designated area 17 on the target surface→the designated area 17 on the target surface gradually leaves the reactive sputtering coating zone 3 (B) in the chamber→the designated area 17 on the target surface enters into the closed cleaning and etching space 4 (C) in the chamber→the compound film 10 in the designated area 17 on the target surface is gradually sputtered and thinned or eliminated (D)→the designated area 17 on the target surface leaves the closed cleaning and etching space 4 (E) in the chamber→the designated area 17 on the target surface gradually enters into the reactive sputtering coating space 3 (F)→the designated area 17 on the target surface fully returns back to (A). Each part of the target surface uniformly conducts the continuous in-situ cleaning to form such a cycle. As a result, even in condition that the reactive gas concentration in the reactive coating space is relatively high, the sputtering working state on the whole target surface can also be maintained relatively stabile in a long term, and the ratio of the formation and removal of the compound film 10 can reach a dynamic balance for a long time in a certain degree that the process needs, so as to avoid the target surface from entering into the poisoning state, develop the deposition rate of the compound film 10 on the substrates, and keep the continuous stability of the process (shown in FIG. 7).

6) As an embodiment of this technique, during the implementation process, in the reactive sputtering coating space 3 of the chamber, in the condition that there is no reactive gas or the concentration of the reactive gas is relatively low or a little quantity of the compound film 10 is formed on the target surface, the assistant power supply 7 for the etching and cleaning can be shut off. Alternatively, based on the operational principle that the continuous in-situ cleaning and etching is conducted for the compound film 10 formed on the target surface, the assistant power supply 7 for the etching and cleaning can be discontinuously turned on or turned off during the operation process to ensure that the reactive sputtering process is continuously stabile in a long term.

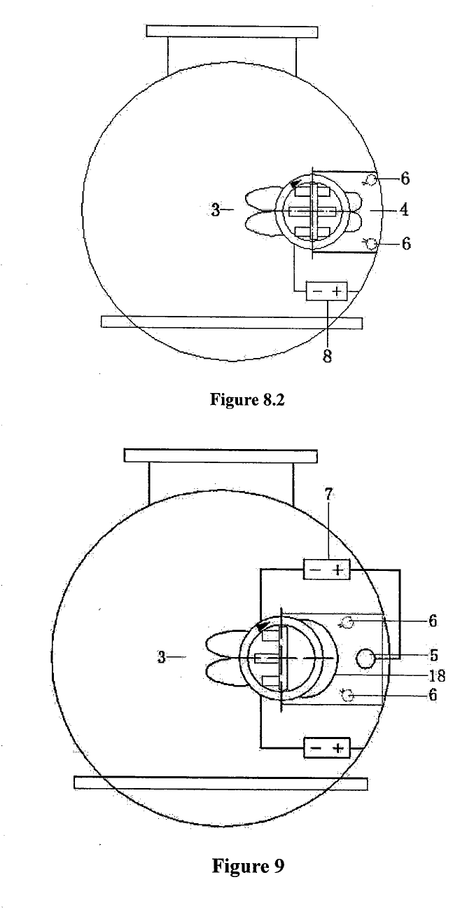

7) As a simplified embodiment of this technique, during the implementation process, the cleaning anode 5 and the main anode (the metal wall of the coater chamber) can be connected together, or as a combined one of the above two anodes uses the part of the main anode exposed in this local space. In these conditions, the assistant power supply 7 for the etching and cleaning can be removed, with only the two sputtering race-tracks mentioned above and the feeding method of the inert gas left; the two sputtering race-tracks share the main anode and is energized and sputtered by one main sputtering power supply 8; in the same way, based on the operational principle that the continuous in-situ cleaning and etching is conducted for the compound film 10 formed on the target surface, it is ensured that the reactive sputtering process is continuously stabile in a long term (shown in FIG. 8.1 and FIG. 8.2).

8) As another simplified embodiment of this technique, the second sputtering race-track 2 mentioned above can be removed during the implementation process: using the inert gas fed in the local space and using the cleaning anode 5 make the target surface in the local space produce the glowing 18 of single arc shape sputtering cleaning and obtain the sputtered etching and cleaning, under an action of the assistant power supply 7 for the etching and cleaning. In the same way, based on the operational principle that the continuous in-situ cleaning and etching is conducted for the compound film 10 formed on the target surface, it is ensured that the reactive sputtering process is continuously stabile in a long term (shown in FIG. 9).

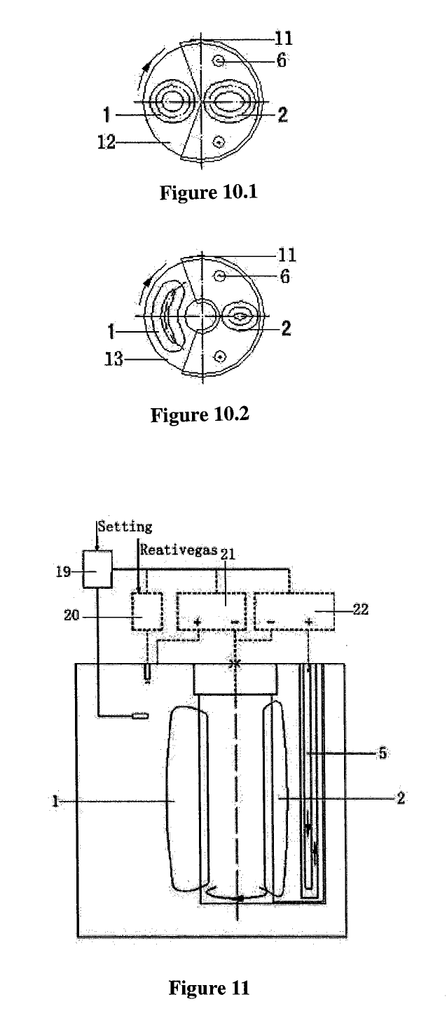

9) Based on the methods and the principle, stated in above items 1)˜8), the target can also be designed as disc target 12 or circular ring target 13; two sputtering race-tracks with the substantially predetermined emitting positions are formed on the outer working surfaces of the disc target or the circular ring target: the first sputtering race-track 1 lies in the sector zone facing to the position of the substrates to be deposited in the coater chamber, and the second sputtering race-track 2 lies in another part of the sector zone. While the first sputtering race-track 1 for the reactive sputtering on the target surface carries on the main sputtering, the second sputtering race-track 2 in the local space carries on the ion etching and cleaning; setting the cleaning anode 5 accordingly and feeding the inert gas makes the pressure in the local space a little higher than (or equal to) the pressure in the reactive sputtering space; let the radial length of the second sputtering race-track 2 along the radius direction is equal to or longer than the radial length of the first sputtering race-track 1. The principle, the operational process, the application method and the simplified methods are the same with that of the cylindrical target mentioned above (shown in FIGS. 10.1 to 10.2).

10) Through properly adjusting power of assistant power supply 7 for the etching and cleaning, or periodically turning on/turning off the assistant power supply 7 for the etching and cleaning and changing the time ratio of the period of turning on and turning off, which match with the ratio of the formation and removal of the compound film 10 on the target surface. As a result, the optimal etching and cleaning effect can be reached, meanwhile not too much target material is consumed.

11) In-situ measure and monitor the characteristic plasma emition spectra, and let the feedback quantity form a closed control loop with one of the following three factors, the power (or current) of the main sputtering power supply 8, the power of the assistant power supply 7 for the etching and cleaning (or the ratio of the currents or the time ratio of the period of turning on and turning off), and the input flow of the reactive working gases. As a result, the reactive coating process can be accurately controlled, and the reproducibility of the process can be ensured (shown in FIG. 11).

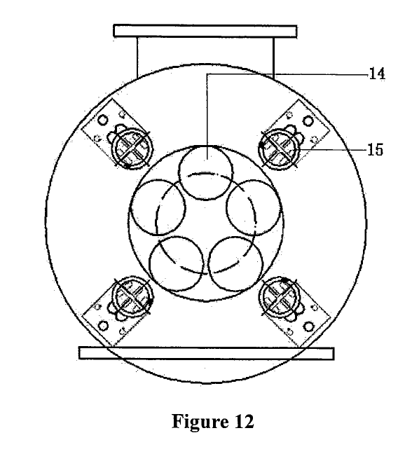

12) Using present invention, when presputtered cleaning the target surface, do not turn on the main sputtering power supply 8 and do not introduce the reactive gas, only use the assistant power supply 7 for the etching and cleaning and feed the inert gas, and only conduct the preetching and cleaning to the rotating target surface in the local space; these measures to be taken are favorable to eliminate the surface pollution of the substrates on the substrate holder 14, which is induced in presputtering and cleaning procedure of the traditional target, and to overcome the weakness such as the cross contamination between the targets in a traditional multi targets system (shown in FIG. 12).

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

I claim:

1. A magnetron with in-situ cleaning target, characters in that it includes: a rotatable magnetron target which may rotate around its central axis; a closed local space formed with shield wall around most part of the area along the target passing route, wherein the inert gas is fed; during the working process of the reactive sputtering deposition, each sputtering part on the target and its vicinal area can be periodically turned into the local space by the target rotating and then is etched and cleaned by ions of the inert gas, so as to make the formation condition of the compound film on the target surface to be stably controlled, and to prevent the target surface from poison.

2. A magnetron with in-situ cleaning target of claim 1, with the following characters:
(1) The shape of the target is cylindrical tube or disc or circular ring, and the target can rotate around its central axis; being in the shape of cylindrical tube, two sputtering race-tracks parallel to the axis and with a substantially predetermined emitting azimuth are formed on the outer surface of the cylindrical tube target by controlling the inner magnetic field of the target: the first sputtering race-track faces to the substrates to be depostited in the sector solid angle space within the coater chamber, and the second sputtering race-track lies in the back or the side face of the first sputtering race-track; when the target is disc or circular ring, two sputtering race-tracks with pre-determined emitting azimuth on the outer working surface of the disc target or the circular ring target are formed by controlling the inner magnetic field of the target: the first sputtering race-track lies in the sector zone facing to the azimuth of the substrates to be deposited in the coater chamber, and the second sputtering race-track lies in another part of the sector zone; the first sputtering race-track is energized and glowed by the equipped main sputtering power supply to carry on the reactive sputtering coating, and the second sputtering race-track is energized and glowed by the equipped assistant power supply for the etching and cleaning to carry on the ion sputtering etching and cleaning, and the wastes produced during the ion sputtered etching and cleaning is closed in the local space formed by the shield wall;
(2) A local space is formed using the shield wall in the part around area of the target passing route, wherein the inert gas is fed; the cleaning anode and the gas distribution device are set in the local space, and feeding of the inert gas makes the pressure of the local space higher than or equal to the pressure of the reactive coating space;
(3) The main sputtering power supply is connected between the target and the main anode of the coater, or an AC sputtering power supply is connected between the two targets, energizing the glowing sputtering at the first sputtering race-track to conduct the sputtering coating; the assistant power supply for the etching and cleaning is connected between the target and the cleaning anode in the local space, energizing the glowing sputtering at the second sputtering race-track to carry on the etching and cleaning on the target surface; the above mentioned main sputtering power supply and the assistant power supply for the etching and cleaning can be separately set or combined into one power supply.

3. The magnetron with in-situ cleaning target of claim 1, wherein: when the shape of the target is cylindrical tube, the axial length of the second race-track is equal to or longer than that of the first one; when the shape of the target is disc or circular ring, the radial length of the second sputtering race-track along the radius direction of the target is equal to or longer than the radial length of the first sputtering race-track.

4. The application method of the magnetron with in-situ cleaning target of claim 1, wherein:
(1) The sputtered part and its vicinal part area on the target surface are periodically turned into the local space and then are etched and cleaned by the inert gas ions, so as to make the formation condition of the compound film on the target surface to be stably controlled and to prevent the target surface from poisoning;
(2) When the reactive sputtering is conducted at the glowing position of the first sputtering race-track, the ion cleaning of the inert gas is conducted for the target at the glowing position of the second sputtering race-track; in this way, while the target is rotating continuously, the relative azimuthes of the two sputtering race-tracks are kept constant, so the whole target surface is cleaned in-situ thoroughly; the compound film formed on the target surface in the reactive coating space can be partly or totally removed by the inert gas ion sputtering at the glowing position of the second sputtering race-track when the target is turned into the inert gas atmosphere in the local space, making the state of the target surface tend to be the metal state or turn into metal state thoroughly when target part turns into the reactive coating area at the second time.

5. The application method of the magnetron with in-situ cleaning target of claim 4, wherein: in the reactive coating space, in condition that there is no reactive gas or the concentration of the reactive gas is relatively low or a little quantity of the compound film is formed on the target surface, the assistant power supply for the etching and cleaning can be shut off, and the assistant power supply for the etching and cleaning can be discontinuously turned on or turned off during the operation process in need.

6. The application method of the magnetron with in-situ cleaning target of claim 4, wherein: the cleaning anode and the main anode is connected together, or as a combined one of the above two anodes uses the exposed part of the main anode in this local space; the above cleaning anode and the main anode have the same electric potential, and the assistant power supply and the main sputtering power supply combined into one supply; by using the arrangement of the two sputtering race-tracks mentioned above and the feeding method of the inert gas in the local space, the two sputtering race-tracks share the main anode and is energized and sputtered by one main sputtering power supply.

7. The application method of the magnetron with in-situ cleaning target of claim 4, wherein: only reserve the first race-track of the said two magnetron sputtering race-tracks; using the inert gas fed in the local space and using the cleaning anode make the target surface in the local space produce a glow discharge and obtain the sputtered etching and cleaning under an action of the assistant power supply for the etching and cleaning.

8. The application method of the magnetron with in-situ cleaning target of claim 4, wherein: when the target is in disc shape or circular ring shape, let the radial length of the second sputtering race-track along the radius direction equal to or longer than the radial length of the first sputtering race-track; while the first sputtering race-track for the reactive sputtering on the target surface carries on the main sputtering, the second sputtering race-track in the local space carries on the ion etching and cleaning, setting the cleaning anode accordingly and feeding the inert gas makes the pressure therein a little higher than or equal to the pressure in the reactive sputtering space.

9. The application method of the magnetron with in-situ cleaning target of claim 4, wherein: through adjusting power of the assistant power supply, or periodically turning on/turning off the assistant power supply, and changing the time ratio of the turning on and the turning off period, which match with the needed ratio of the formation and removal of the compound film on the target surface, so as to reach the optimal etching and cleaning effect, meanwhile not too much target material consumed.

10. The application method of the magnetron with in-situ cleaning target of claim 4, wherein: in-situ detect and monitor the characteristic plasma emitting spectra in the vicinity of the target surface during the sputtering deposition, and let the feedback quantity form a closed control loop with one of the following three factors, the power or the current of the main sputtering power supply, the power of the assistant power supply for the etching and cleaning or the ratio of the currents or the time ratio of the turning on and turning off period, and the input flow of the reactive working gases; so as to accurately control the reactive coating process and to ensure the reproducibility of the process.

11. The application method of the magnetron with in-situ cleaning target of claim 4, wherein: when pre sputtered cleaning the target surface, do not turn on the main sputtering power supply and do not introduce the reactive gas, only use the assistant power supply and feed the inert gas, and only conduct the pre etching and cleaning to the rotating target surface in the local space; these measures are favorable to eliminate the surface pollution of the substrates on the deposited substrate holder, which is induced in pre sputtering and cleaning procedure of the traditional target, and to overcome the process weakness such as the cross contamination between the targets in the traditional multi targets system.
